(19) United States
(12) Patent Application Publication
(10) Pub. No.: US 2013/0301340 A1
(43) Pub. Date: Nov. 14, 2013

(54) ERASING METHOD OF RESISTIVE RANDOM ACCESS MEMORY

(71) Applicant: SAMSUNG ELECTRONICS CO., LTD., SUWON-SI (KR)

(72) Inventors: JINTAEK PARK, Hwaseong-Si (KR); Youngwoo Park, Seoul (KR); Jungdal Choi, Hwaseong-Si (KR)

(73) Assignee: SAMSUNG ELECTRONICS CO., LTD., SUWON-SI (KR)

(21) Appl. No.: 13/796,808

(22) Filed: Mar. 12, 2013

(30) Foreign Application Priority Data
May 14, 2012 (KR) 10-2012-0050919

(51) Int. Cl. G11C 13/00

(52) U.S. Cl. CPC G11C 13/0097
USPC 365/148

(57) ABSTRACT

An erase method of a resistive random access memory which includes a plurality of cell strings, each having a plurality of memory cells and a string selection transistor, includes applying a first voltage to bit lines connected with string selection transistors of the plurality of cell strings, applying a turn-on voltage to at least one string selection line selected from string selection lines connected with the string selection transistors, applying a turn-off voltage to unselected string selection lines of the string selection lines, applying a second voltage to at least one word line selected from word lines connected with memory cells of the plurality of cell strings, and floating unselected word lines of the word lines.

### CROSS-REFERENCE TO RELATED APPLICATION

This application claims under 35 U.S.C. §119 priority to and the benefit of Korean Patent Application No. 10-2012-0050919 filed on May 14, 2012 in the Korean Intellectual Property Office, the entire contents of which are incorporated by reference herein.

### BACKGROUND

1. Technical Field

The present disclosure relates to a semiconductor memory, and, more particularly, relates to a method of erasing a resistive random access memory.

2. Discussion of Related Art

A semiconductor memory device is a memory device which is fabricated using semiconductors such as silicon (Si), germanium (Ge), gallium arsenide (GaAs), indium phosphide (InP), and the like. Semiconductor memory devices are classified into volatile memory devices and nonvolatile memory devices.

The volatile memory devices may lose stored contents at power-off. The volatile memory devices include various random access memory (RAM) devices, such as a static RAM (SRAM), a dynamic RAM (DRAM), a synchronous DRAM (SDRAM), and the like. The nonvolatile memory devices may retain stored contents even at power-off. The nonvolatile memory devices include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), and the like. The flash memory device is roughly divided into a NOR type and a NAND type.

The typical RRAM operates by changing the resistance of a dielectric material in a memory cell. While dielectric material does not normally conduct electric current, if the dielectric material is subjected to a high enough voltage, it will suddenly conduct because of a phenomenon called dielectric breakdown. The deliberately applied voltage causes the medium to acquire microscopic conductive paths called filaments. The filaments appear as a result of various phenomena such as metal migration or physical defects. Once a filament appears, it can be broken or reversed by the application of a different external voltage. The controlled formation and destruction of the filaments in large numbers allows for storage of digital data.

The RRAM has the potential to become a front runner amongst other nonvolatile memories. As compared to the PRAM, the RRAM operates at a faster timescale, while as compared to MRAM, it has a simpler, smaller cell structure. As compared to flash memory, a lower voltage is sufficient for the RRAM and hence it can be used in low power applications. However, a need still exists for an effective method for erasing an RRAM.

### SUMMARY

Exemplary embodiments of the inventive concept provide an erase method of an RRAM device which includes a plurality of cell strings each having a plurality of memory cells and a string selection transistor. The erase method includes applying a first voltage to bit lines connected with string selection transistors of the plurality of cell strings, applying a turn-on voltage to at least one string selection line selected from string selection lines connected with the string selection transistors, applying a turn-off voltage to unselected string selection lines of the string selection lines, applying a second voltage to at least one word line selected from word lines connected with memory cells of the plurality of cell strings, and floating unselected word lines of the word lines.

In an exemplary embodiment, the first and second voltages are established to reset a selected memory cell.

In an exemplary embodiment, the second voltage is a ground voltage.

In an exemplary embodiment, the string selection lines and the word lines are selected by a unit of at least one memory block.

In an exemplary embodiment, the word lines are selected by a unit of at least one memory block and the string selection lines are selected by a unit of at least one string selection line.

In an exemplary embodiment, the word lines are selected by a unit of at least one word line and the string selection lines are selected by a unit of at least one memory block.

In an exemplary embodiment, the word lines are selected by a unit of at least one word line and the string selection lines are selected by a unit of at least one string selection line.

In an exemplary embodiment, the erase method further includes selecting one of a plurality of erase units. The number of the selected at least one word line and the number of the selected at least one string selection line vary according to the selected erase unit.

In an exemplary embodiment, the erase method further includes performing an erase verification operation. The erase verification operation comprises applying a turn-on voltage to the selected at least one string selection line, applying a turn-off voltage to the unselected string selection lines, applying a verification voltage to the selected at least one word line, floating the unselected word lines, and sensing a current flowing through the bit lines.

In an exemplary embodiment, the erase method further includes again erasing the plurality of memory cells when the erase verification operation is determined to be failed. The again erasing comprises applying a third voltage higher than the first voltage to the bit lines connected with the string selection transistors of the plurality of cell strings, applying the turn-on voltage to the at least one string selection line selected from the string selection lines connected with the string selection transistors, applying the turn-off voltage to the unselected string selection lines of the string selection lines, applying the second voltage to the at least one word line selected from the word lines connected with the memory cells of the plurality of cell strings; and floating the unselected word lines of the word lines.

Exemplary embodiments of the inventive concept also provide an erase method of an RRAM which includes a plurality of cell strings each having a plurality of memory cells and a string selection transistor. The erase method includes applying a first voltage to at least one bit line selected from bit lines connected with string selection transistors of the plurality of cell strings, floating unselected bit lines of the bit lines; applying a turn-on voltage to at least one string selection line selected from string selection lines connected with the string selection transistors, applying a turn-off voltage to unselected string selection lines of the string selection lines; applying a second voltage to at least one word line selected from word lines connected with memory cells of the plurality of cell strings, and floating unselected word lines of the word lines.

In an exemplary embodiment, the bit lines are selected by a unit of at least one bit line, the string selection lines are selected by a unit of at least one memory block, and the word lines are selected by a unit of at least one memory block.

In an exemplary embodiment, the bit lines are selected by a unit of at least one bit line, the string selection lines are selected by a unit of at least string selection line, and the word lines are selected by a unit of at least one memory block.

In an exemplary embodiment, the bit lines are selected by a unit of at least one bit line, the string selection lines are selected by a unit of at least one memory block, and the word lines are selected by a unit of at least one word line.

In an exemplary embodiment, the bit lines are selected by a unit of at least one bit line, the string selection lines are selected by a unit of at least string selection line, and the word lines are selected by a unit of at least one word line.

In an exemplary embodiment, the erase method further includes selecting one of a plurality of erase units. The number of the selected at least one bit line, the number of the selected at least word line, and the number of the selected at least one string selection line vary according to the selected erase unit.

In an exemplary embodiment, a method of controlling erasure and non-erasure of resistive random access memory cell strings of a memory array is provided. The method includes coupling the resistive random access memory cell strings to a bit line, a current flowing through the memory cell strings being controlled by a voltage applied to a respective string selection transistor of each resistive random access memory cell string, each cell of the memory string being coupled to a respective word line. The resistive random access memory cell strings are erased by applying a first voltage to the bit line, applying a turn-on voltage to each respective string selection transistor, and applying a second voltage to each word line. The resistive random access memory cell strings are not erased by applying the first voltage to the bit line, applying a turn-off voltage to each respective string selection transistor, and floating each word line.

In an exemplary embodiment the first voltage may be a positive reset voltage.

In an exemplary embodiment the turn-on voltage may be a power supply voltage.

In an exemplary embodiment the turn-off voltage and the second voltage may both be ground voltages.

### BRIEF DESCRIPTION OF THE DRAWINGS

The exemplary embodiments will now be described with reference to the following figures, wherein like reference numerals refer to like parts throughout the various figures unless otherwise specified.

FIG. 1 is a block diagram schematically illustrating an RRAM according to an exemplary embodiment of the inventive concept.

FIG. 2 is a diagram schematically illustrating a memory cell array in FIG. 1.

FIG. 3 is a circuit diagram schematically illustrating a part of a memory block in FIG. 2.

FIG. 4 is a graph illustrating hysteresis curves of memory cells in FIG. 3.

FIG. 5 is a flowchart illustrating an erase method according to an exemplary embodiment of the inventive concept.

FIGS. 6A, 6B and 6C are diagrams illustrating an exemplary embodiment whereby an erase operation is performed by the memory block.

FIGS. 7A and 7B are diagrams illustrating an exemplary embodiment whereby an erase operation is performed by a unit of a first plane.

FIGS. 8A and 8B are diagrams illustrating an exemplary embodiment whereby an erase operation is performed by the word line.

FIGS. 9A and 9B are diagrams illustrating an exemplary embodiment whereby an erase operation is performed by the page.

FIGS. 10A and 10B are diagrams illustrating an exemplary embodiment whereby an erase operation is performed by a unit of a second plane.

FIGS. 11A and 11B are diagrams illustrating an exemplary embodiment whereby an erase operation is performed by the cell string.

FIGS. 12A and 12B are diagrams illustrating an exemplary embodiment whereby an erase operation is performed by a unit of a row string.

FIGS. 13A and 13B are diagrams illustrating an exemplary embodiment whereby an erase operation is performed by the memory cell.

FIG. 14 is a flowchart illustrating an erase method according to an exemplary embodiment of the inventive concept.

FIGS. 15A and 15B are diagrams illustrating an example of an erase verification operation.

FIG. 16 is a diagram illustrating an example wherein an erase operation and an erase verification operation are iterated.

FIG. 17 is a flowchart illustrating an erase method according to an exemplary embodiment of the inventive concept.

FIG. 18 is a block diagram illustrating a memory system according to an exemplary embodiment of the inventive concept.

FIG. 19 is a block diagram schematically illustrating a computing system according to an exemplary embodiment of the inventive concept.

### DETAILED DESCRIPTION

Embodiments will be described in detail with reference to the accompanying drawings. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

The term “selected bit line” or “selected bit lines” may indicate a bit line or bit lines connected to cells to be erased (or, to be erase verified). The term “unselected bit line” or “unselected bit lines” may indicate a bit line or bit lines connected to cells to be erase inhibited.

The term “selected string selection line” or “selected string selection lines” may indicate a string selection line or string selection lines connected with a cell string or cell strings including memory cells to be erased (or, to be erase verified). The term “unselected string selection line” or “unselected string selection lines” may indicate the remaining string selection line or string selection lines except the selected string selection line or string selection lines. The term “selected string selection transistors” may indicate string selection transistors connected with the selected string selection line or string selection lines. The term “unselected string selection transistors” may indicate string selection transistors connected with the unselected string selection line or string selection lines.

The term “selected word line” or “selected word lines” may indicate a word line or word lines connected to cells to be erased (or, to be erase verified). The term “unselected word line” or “unselected word lines” may indicate the remaining word line or word lines except the selected word line or word lines.

The term “selected memory cell” or “selected memory cells” may indicate a memory cell or memory cells to be erased (or, to be erase verified). The term “unselected memory cell” or “unselected memory cells” may indicate the remaining memory cell or memory cells except the selected memory cell or memory cells.

In an exemplary embodiment, the inventive concept will be described with reference to an RRAM. However, the inventive concept is not limited to the resistive memory device. The inventive concept can be applied to various memories such as an EEPROM, a NAND flash memory device, a NOR flash memory device, a PRAM, an MRAM), a FRAM, and the like.

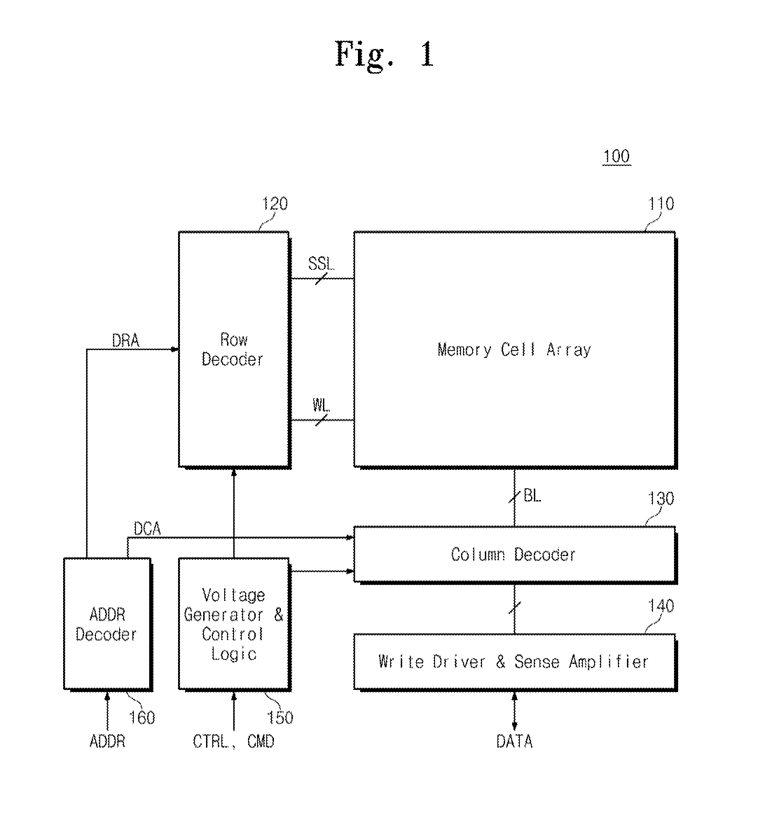

FIG. 1 is a block diagram schematically illustrating an RRAM according to an exemplary embodiment of the inventive concept. Referring to FIG. 1, an RRAM 100 according to an exemplary embodiment of the inventive concept may include a memory cell array 110, a row decoder 120, a column decoder 130, a write driver and sense amplifier block 140, voltage generator and control logic 150, and an address decoder 160.

The memory cell array 110 may be connected to the row decoder 120 via word lines WL and to the column decoder 130 via bit lines BL. The memory cell array 110 may include a plurality of memory cells. In an exemplary embodiment, memory cells arranged in a row direction may be connected to word lines WL, and memory cells arranged in a column direction may be connected to bit lines BL. The memory cell array 110 may include multiple memory cells each storing one or more bits of data. The plurality of memory cells may form cell strings, each of which includes memory cells and a string selection transistor.

The row decoder 120 may be connected to the memory cell array 110 via the word lines WL and string selection lines SSL. The row decoder 120 may operate responsive to the control of the voltage generator and control logic 150. The row decoder 120 may select the word lines WL and the string selection lines SSL in response to a decoded row address DRA from the address decoder 160. The row decoder 120 may be supplied with power (e.g., a voltage or a current) from the voltage generator and control logic 150 to transfer it to the word lines WL and the string selection lines SSL.

The column decoder 130 may be connected to the memory cell array 110 via the bit lines BL. The column decoder 130 may operate responsive to the control of the voltage generator and control logic 150. The column decoder 130 may select the bit lines BL in response to a decoded column address DCA from the address decoder 160. The column decoder 130 may be supplied with power (e.g., a voltage or a current) from the voltage generator and control logic 150 to transfer it to the bit lines BL.

The write driver and sense amplifier block 140 may be connected to the bit lines BL via the column decoder 130. The write driver and sense amplifier block 140 may operate responsive to the control of the voltage generator and control logic 150. The write driver and sense amplifier block 140 may be configured to write data at memory cells connected to bit lines selected by the column decoder 130 or to read data therefrom. Data read by the write driver and sense amplifier block 140 may be output to an external device. Data provided to the write driver and sense amplifier block 140 may be written at memory cells.

The voltage generator and control logic 150 may be configured to control the overall operation of the RRAM 100. The voltage generator and control logic 150 may operate responsive to input control signal CTRL and command CMD. The voltage generator and control logic 150 may control reading, writing, or erasing of the RRAM 100.

The address decoder 160 may decode a row address of an input address ADDR to provide it to the row decoder 120. The address decoder 160 may decode a column address of the input address ADDR to provide it to the column decoder 130.

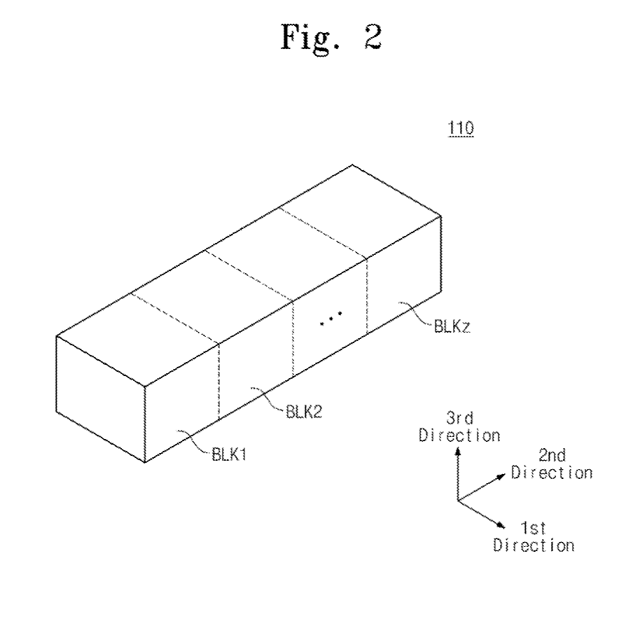

FIG. 2 is a diagram schematically illustrating a memory cell array in FIG. 1. Referring to FIGS. 1 and 2, a memory cell array 110 may include a plurality of memory blocks BLK1, BLK2, . . . BLKz, each of which has a three-dimensional structure (e.g., a 1^{st} direction, 2^{nd} direction and 3^{rd} direction, as shown, or, merely a vertical structure. Each memory block may include a plurality of cell strings extending along a direction perpendicular to a substrate.

Cell strings in one memory block may be connected to a plurality of bit lines BL, a plurality of string selection lines SSL, and a plurality of word lines WL. Cell strings in the memory blocks BLK1, BLK2, . . . BLKz may share the plurality of bit lines BL.

The memory blocks BLK1, BLK2, . . . BLKz may be selected by a row decoder 120 illustrated in FIG. 1. For example, the row decoder 120 may be configured to select a memory block, corresponding to a decoded row address DRA, from among the memory blocks BLK1, BLK2, . . . BLKz. Programming, reading, and erasing may be performed at a selected memory block.

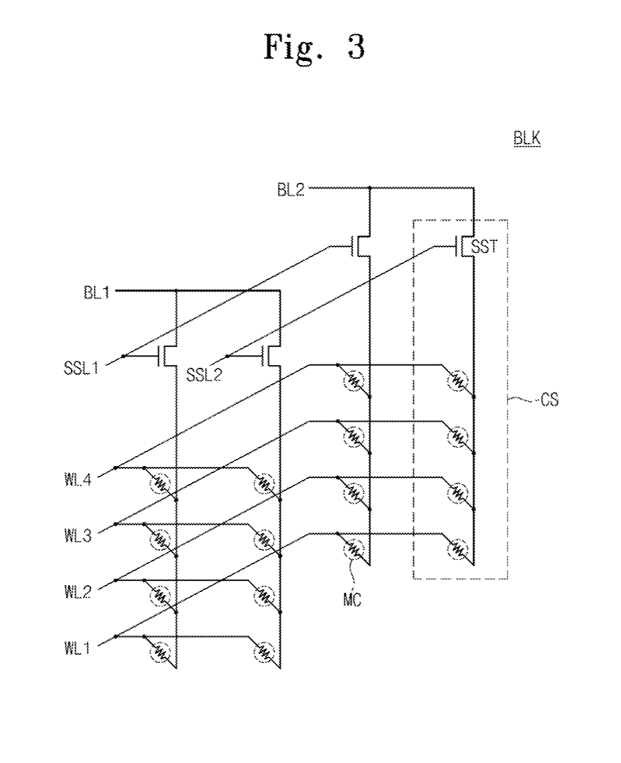

FIG. 3 is a circuit diagram schematically illustrating a part of a memory block in FIG. 2. Referring to FIG. 3, a memory block BLK may include a plurality of cell strings CS.

Each cell string CS may include memory cells MC and a string selection transistor SST that are connected in series. In each cell string CS, memory cells MC may be connected with word lines WL1, WL2, WL3, WL4, respectively. The string selection transistor SST may be connected with a bit line BL1, BL2 according to the control of a string selection line SSL1, SSL2.

The cell strings CS may be arranged along rows and columns. Cell strings placed at the same row may share bit lines BL1, BL2. Cell strings placed at the same column may share string selection lines SSL1, SSL2. Memory cells MC placed in the same order away from the string selection transistors SST may share respective word lines WL1, WL2, WL3, WL4.

Each memory cell may include a variable dielectric or resistor such that each memory cell can have a resistance value variable according to an applied voltage or current.

In an exemplary embodiment, a memory block BLKa including four cell strings CS connected with two bit lines BL1, BL2, two string selection lines SSL1, SSL2, and four word lines WL1, WL2, WL3, WL4 is illustrated in FIG. 3. However, the inventive concept is not limited thereto. In the memory block BLKa, the number of cell strings, the number of bit lines, the number of string selection lines, and the number of word lines may vary.

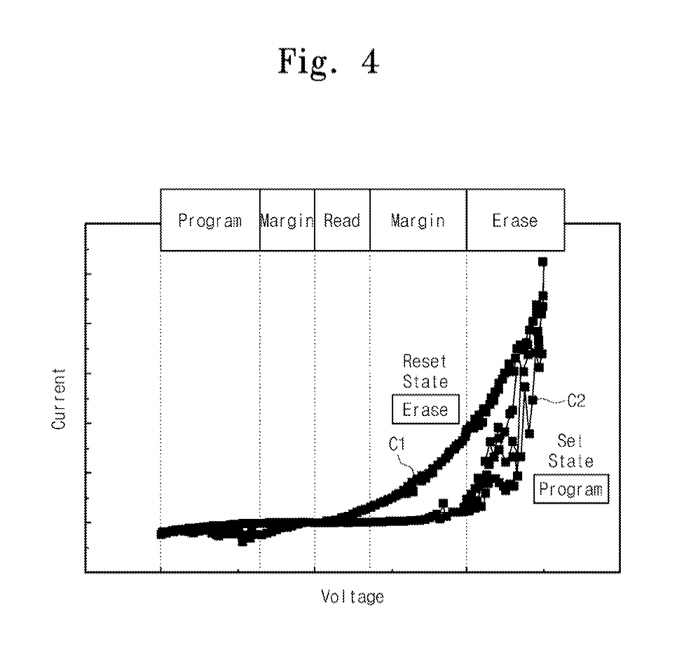

FIG. 4 is a graph illustrating hysteresis curves of the memory cells in FIG. 3. In FIG. 4, the horizontal axis indicates voltage and the vertical axis indicates current. At the top of FIG. 4, the condition that memory cells MC transitions between a reset state (or, an erase state) and a set state (or, a program state) is illustrated using voltage periods.

A first curve C1 is a voltage-current curve of memory cells having a reset state (or, an erase state). A second curve C2 is a voltage-current curve of memory cells having a set state (or, a program state).

When the same voltage (e.g., a voltage having a level belonging to a read period) is applied to memory cells MC, the amount of a current flowing via a memory cell MC having a reset state (or, an erase state) may be more than that of a memory cell having a set state (e.g., a program state). That is, a memory cell MC of a set state (or, a program state) may have a resistance value larger than that of a memory cell of a reset state (or, an erase state).

When a voltage corresponding to an erase period is applied to memory cells having a set state (or, a program state), states of the memory cells may be changed into a reset state (or, an erase state). Alternatively, when a current corresponding to a voltage of an erase period is applied to memory cells having a set state (or, a program state), states of the memory cells may be changed into a reset state (or, an erase state).

If a voltage corresponding to a program period is applied to memory cells having a reset state (or, an erase state), states of the memory cells may be changed into a set state (or, a program state). Alternatively, when a current corresponding to a voltage of a program period is applied to memory cells having a reset state (or, an erase state), states of the memory cells may be changed into a set state (or, a program state).

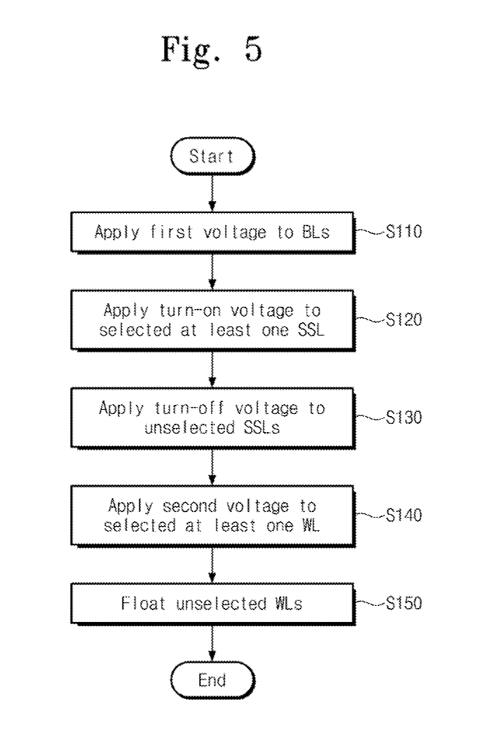

FIG. 5 is a flowchart illustrating an erase method according to an exemplary embodiment of the inventive concept. Referring to FIGS. 3 and 5, in operation S110, a first voltage may be applied to bit lines BL1, BL2.

In operation S120, a turn-on voltage may be applied to at least one selected string selection line. The turn-on voltage may have a level sufficient to turn on selected string selection transistors.

In operation S130, a turn-off voltage may be applied to unselected string selection lines. The turn-off voltage may have a level sufficient to turn off unselected string selection transistors.

In operation S140, a second voltage may be supplied to at least one selected word line.

In operation S150, unselected word lines may be floated.

The first and second voltages may be established to erase selected memory cells. The first voltage may be a positive voltage, and the second voltage may be a ground voltage VSS.

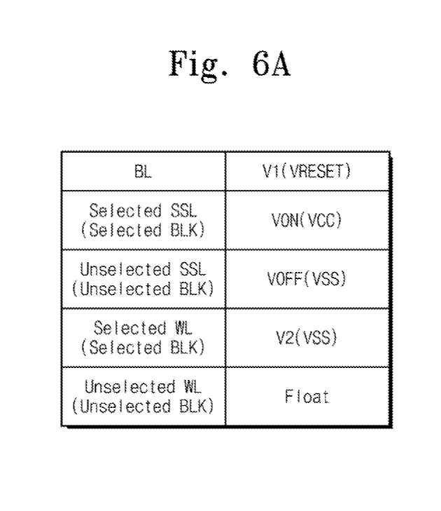

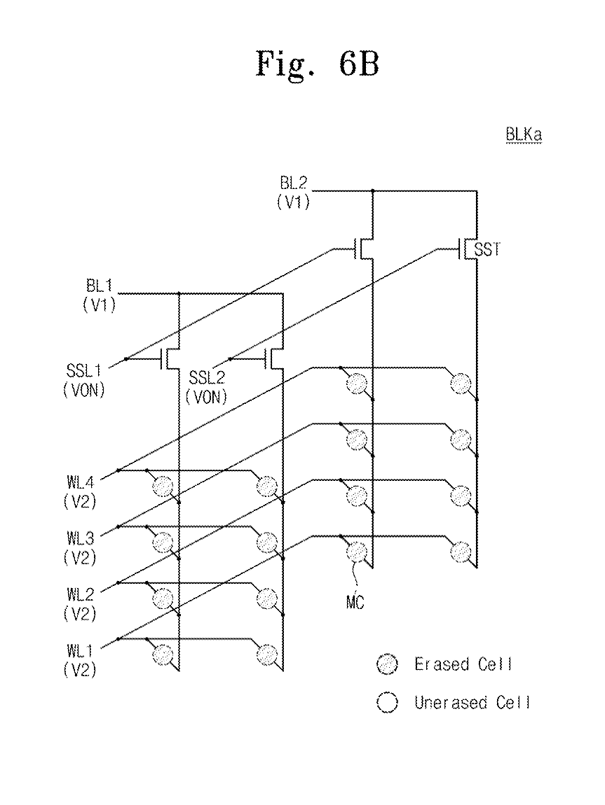

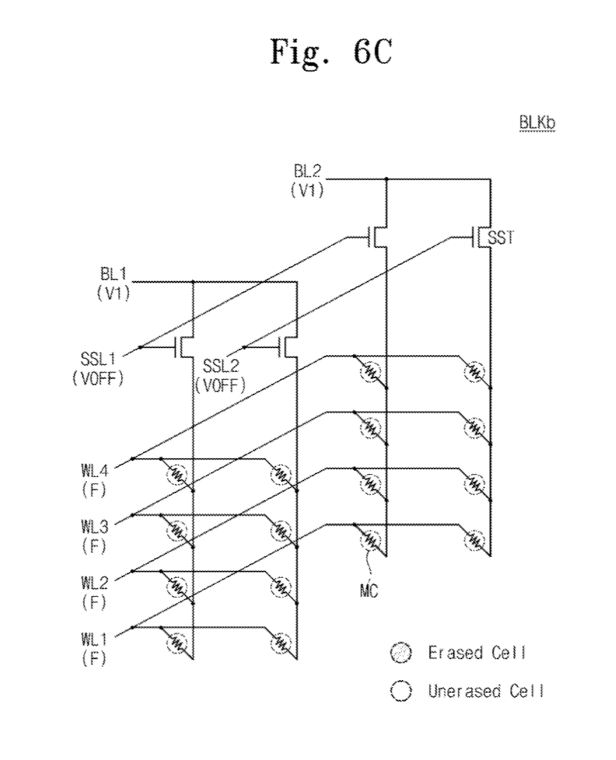

FIGS. 6A, 6B and 6C are diagrams illustrating an exemplary embodiment whereby an erase operation is performed by the memory block. Referring to FIG. 6A, there is illustrated a voltage condition of an erase operation executed by the memory block. A first voltage V1 may be applied to bit lines BL. The first voltage V1 may be a reset voltage VRESET having a level corresponding to an erase period in FIG. 4. The reset voltage VRESET may be a positive voltage.

A turn-on voltage VON may be provided to selected string selection lines. The turn-on voltage may be a power supply voltage VCC. A turn-off voltage may be applied to unselected string selection lines. The turn-off voltage VOFF may be a ground voltage VSS.

A second voltage V2 may be supplied to selected word lines. The second voltage V2 may be a ground voltage VSS. Unselected word lines may be floated.

FIG. 6B shows an example wherein voltages are applied to a selected memory block BLKa according to the voltage conditions in FIG. 6A. Referring to FIG. 6B, the first voltage V1 may be applied to bit lines BL1, BL2, and a turn-on voltage VON may be provided to string selection lines SSL1, SSL2. The second voltage V2 may be provided to word lines WL1, WL2, WL3, WL4.

A current may flow into the word lines WL1, WL2, WL3, WL4 through memory cells MC from the bit lines BL1, BL2. The memory cells MC of the selected memory cells BLKa may be erased by the current.

FIG. 6C shows an example wherein voltages are applied to an unselected memory block BLKb according to the voltage conditions in FIG. 6A. Referring to FIG. 6C, since the bit lines BL1, BL2 are shared by the selected memory block BLKa, the first voltage V1 may be applied to the bit lines BL1, BL2. A turn-off voltage VOFF may be provided to the string selection lines SSL1, SSL2, and the word lines WL1, WL2, WL3, WL4 may be floated.

Since the string selection transistors SST are turned off, the bit lines BL1, BL2 may be electrically separated from the memory cells MC. Since no current flows through memory cells MC, memory cells MC in the unselected memory block BLKb can not be erased.

When an erase operation is performed by a unit of at least one memory block, string selection lines and word lines may be selected by a unit of at least one memory block. If an erase operation is carried out by the memory block, string selection lines and word lines in a selected memory block all may be selected. In the case where an erase operation is carried out by a unit of two memory blocks, string selection lines and word lines in two selected memory blocks may all be selected.

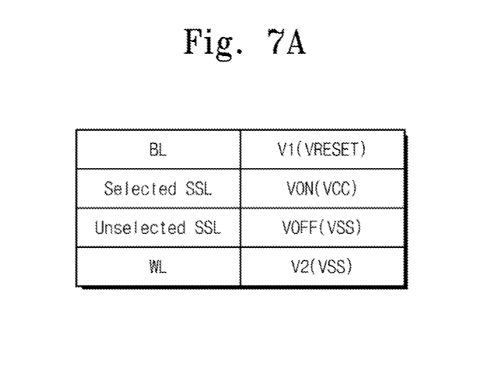

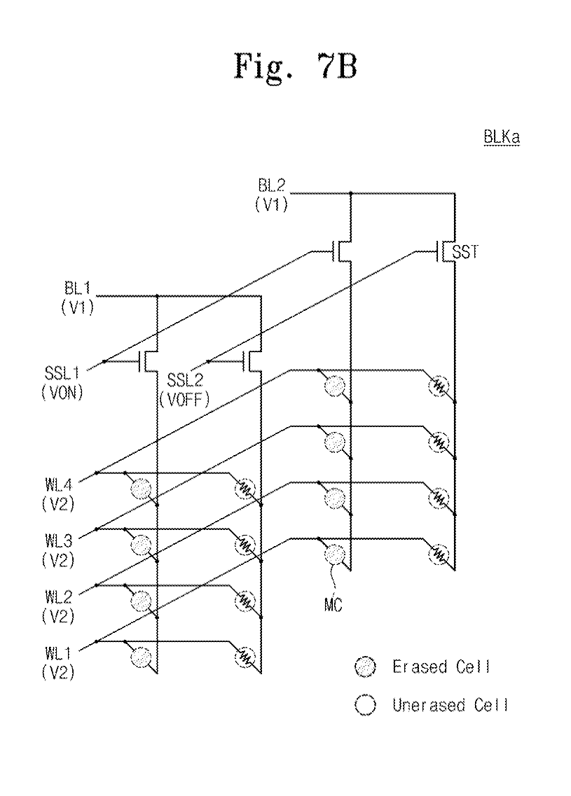

FIGS. 7A and 7B are diagrams illustrating an exemplary embodiment whereby an erase operation is performed by a unit of a first plane of the memory cell array. Referring to FIG. 7A, there is illustrated a voltage condition of an erase operation executed by a unit of a first plane. A first voltage V1 may be applied to bit lines BL1. The first voltage V1 may be a reset voltage VRESET. The reset voltage VRESET may be a positive voltage.

A turn-on voltage VON may be supplied to selected string selection lines. The turn-on voltage VON may be a power supply voltage VCC. A turn-off voltage VOFF may be applied to unselected string selection lines. The turn-off voltage VOFF may be a ground voltage VSS. A second voltage V2 may be provided to word lines. The second voltage V2 may be a ground voltage VSS.

In an exemplary embodiment, FIG. 7A shows a voltage condition of bit lines, string selection lines, and word lines of a selected memory block to be erased. A voltage condition of an unselected memory block to be erase-inhibited may be the same as that illustrated in FIG. 6C.

FIG. 7B shows an example wherein voltages are applied to a selected memory block BLKa according to the voltage condition in FIG. 7A. Referring to FIG. 7B, the first voltage V1 may be applied to bit lines BL1, BL2. A turn-on voltage VON may be provided to a selected string selection line SSL1, and a turn-off voltage VOFF may be applied to an unselected string selection line SSL2. The second voltage V2 may be provided to word lines WL1, WL2, WL3, WL4.

String selection transistors SST connected with the selected string selection line SSL1 may be turned on. That is, a current may flow through memory cells MC of cell strings CS connected with the selected string selection line SSL1. At this time, memory cells MC may be erased.

String selection transistors SST connected with the unselected string selection line SSL2 may be turned off. That is, no current can flow through memory cells MC of cell strings CS connected with the unselected string selection line SSL2. At this time, memory cells MC can not be erased.

The first plane may be formed of memory cells MC of cell strings CS connected with a string selection line SSL. When an erase operation is performed by a unit of at least first plane, string selection lines SSL1, SSL2 may be selected by a unit of at least one string selection line SSL, and word lines WL1, WL2, WL3, WL4 may be selected by the memory block BLKa.

For example, when an erase operation is performed by a unit of the first plane, a particular string selection line SSL corresponding to the selected first plane may be selected, and all word lines WL1, WL2, WL3, WL4 of the selected memory block BLKa may be selected. When an erase operation is performed by a unit of two first planes, string selection lines SSL corresponding to the selected first planes may be selected, and all word lines WL1, WL2, WL3, WL4 of the selected memory block BLKa may be selected.

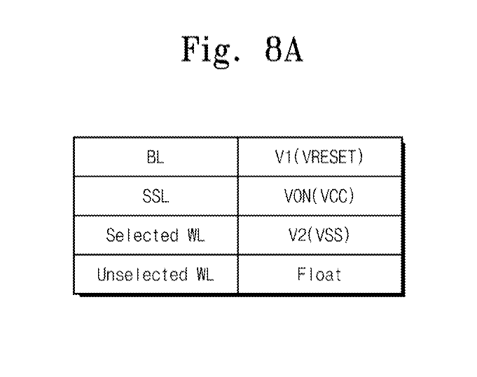

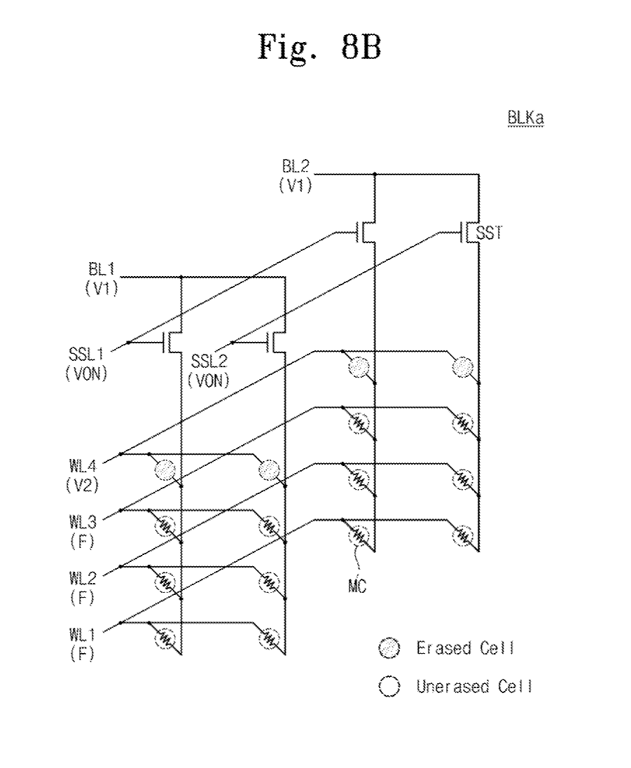

FIGS. 8A and 8B are diagrams illustrating an exemplary embodiment whereby an erase operation is performed by the word line. Referring to FIG. 8A, there is illustrated a voltage condition of an erase operation executed by the word line. A first voltage V1 may be applied to bit lines BL. The first voltage V1 may be a reset voltage VRESET. The reset voltage VRESET may be a positive voltage.

A turn-on voltage VON may be provided to string selection lines. The turn-on voltage may be a power supply voltage VCC. A second voltage V2 may be applied to selected word lines. The second voltage V2 may be a ground voltage VSS. Unselected word lines may be floated.

In an exemplary embodiment, FIG. 8A shows a voltage condition of bit lines, string selection lines, and word lines of a selected memory block to be erased. A voltage condition of an unselected memory block to be erase-inhibited may be identical to that illustrated in FIG. 6C.

FIG. 8B shows an example wherein voltages are applied to a selected memory block BLKa according to the voltage condition in FIG. 8A. Referring to FIG. 8B, the first voltage V1 may be applied to bit lines BL1, BL2. A turn-on voltage VON may be provided to string selection lines SSL1, SSL2. The second voltage V2 may be provided to a selected word line WL4, and unselected word lines may be floated.

String selection transistors SST connected with the string selection lines SSL1, SSL2 may be turned on. Since the second voltage V2 is applied to the selected word line WL4, a current may flow into the selected word line WL4 through string selection transistors SST and memory cells MC from the bit lines BL1, BL2. Memory cells MC connected with the selected word line WL4 may be erased by the current.

Since the unselected word lines WL1, WL2, WL3 are floated, no current can flow into the unselected word lines WL1, WL2, WL3 through string selection transistors SST and memory cells MC from the bit lines BL1, BL2. Memory cells MC connected with the unselected word lines WL1 to WL3 can not be erased.

When an erase operation is performed by the word line, word lines WL1, WL2, WL3, WL4 may be selected by a unit of at least one word line, and string selection lines SSL1, SSL2 may be selected by the memory block BLKa.

For example, when an erase operation is performed by the word line, one word line WL may be selected, and all string selection lines SSL1, SSL2 of a selected memory block BLKa may be selected. When an erase operation is performed by a unit of two word lines, two word lines WL may be selected, and all string selection lines SSL1, SSL2 of a selected memory block BLKa may be selected.

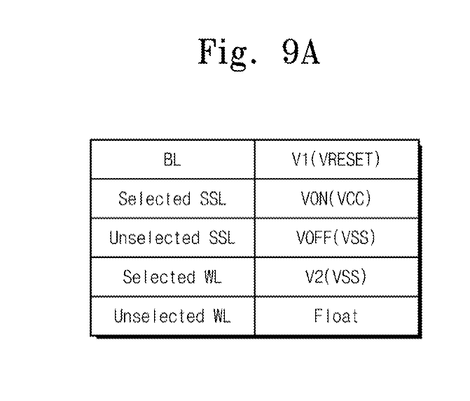

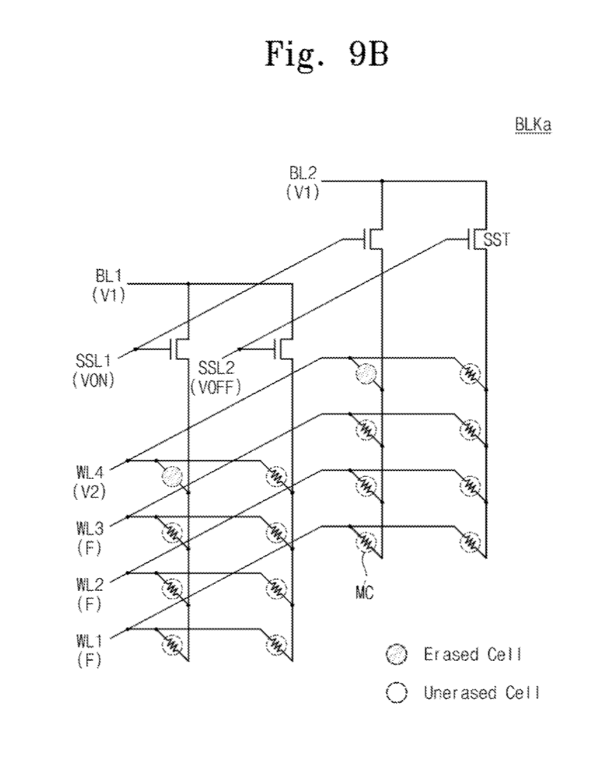

FIGS. 9A and 9B are diagrams illustrating an exemplary embodiment whereby an erase operation is performed by the page. Referring to FIG. 9A, there is illustrated a voltage condition of an erase operation executed by the page. A first voltage V1 may be applied to bit lines BL. The first voltage V1 may be a reset voltage VRESET. The reset voltage VRESET may be a positive voltage.

A turn-on voltage VON may be provided to selected string selection lines. The turn-on voltage may be a power supply voltage VCC. A turn-off voltage may be applied to unselected string selection lines. The turn-off voltage VOFF may be a ground voltage VSS. A second voltage V2 may be supplied to selected word lines. The second voltage V2 may be a ground voltage VSS. Unselected word lines may be floated.

In an exemplary embodiment, FIG. 9A shows a voltage condition of bit lines, string selection lines, and word lines of a selected memory block to be erased. A voltage condition of an unselected memory block to be erase-inhibited may be identical to that illustrated in FIG. 6C.

FIG. 9B shows an example wherein voltages are applied to a selected memory block BLKa according to the voltage condition in FIG. 9A. Referring to FIG. 9B, the first voltage V1 may be applied to bit lines BL1, BL2. A turn-on voltage VON may be provided to a selected string selection line SSL1, a turn-off voltage VOFF may be applied to an unselected string selection line SSL2. The second voltage V2 may be provided to a selected word line WL4, and unselected word lines WL1 to WL3 may be floated.

String selection transistors SST connected with the string selection line SSL2 may be turned off. That is, memory cells MC of cell strings CS connected with the string selection line SSL2 can not be erased. Unselected word lines WL1, WL2, WL3 may be floated. That is, memory cells connected with the unselected word lines WL1, WL2, WL3 can not be erased.

A current may flow through memory cells MC corresponding to the selected SSL1 and WL4. That is, memory cells MC corresponding to the selected SSL1 and WL4 may be erased.

A page may be formed of memory cells corresponding to a word line and a string selection line in common. When an erase operation is performed by a unit of at least one page, word lines WL1, WL2, WL3, WL4 may be selected by a unit of at least one word line, and string selection lines SSL1, SSL2 may be selected by a unit of at least one string selection line.

For example, when an erase operation is performed by the page, one word line WL corresponding to a selected page and one string selection line SSL may be selected. When an erase operation is performed by a unit of two pages, two word lines WL and string selection lines SSL corresponding to the selected pages may be selected.

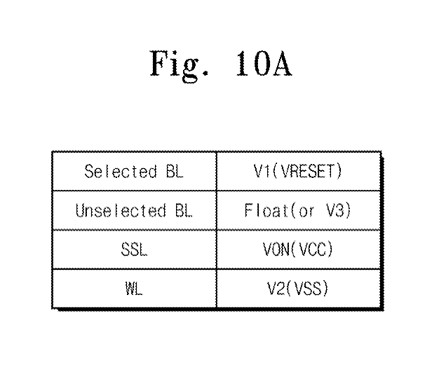

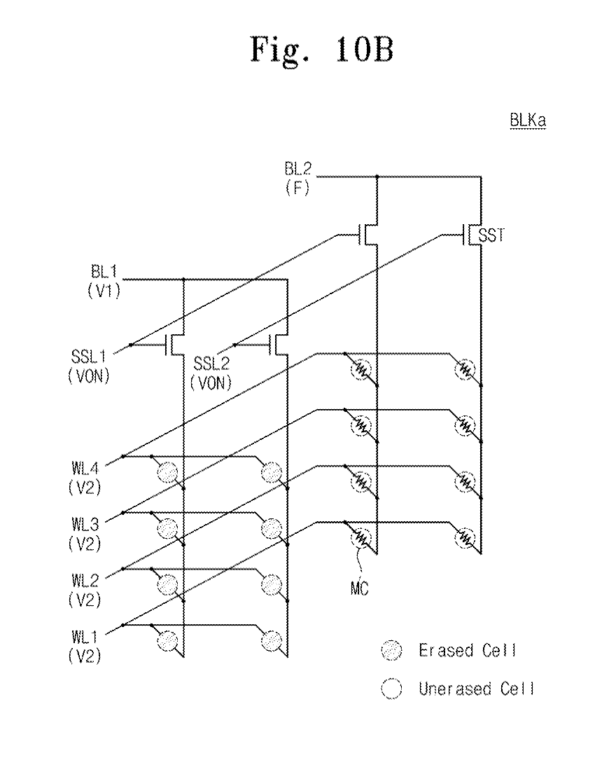

FIGS. 10A and 10B are diagrams illustrating an exemplary embodiment whereby an erase operation is performed by a unit of a second plane of the memory cell array. Referring to FIG. 10A, there is illustrated a voltage condition of an erase operation executed by the second plane. A first voltage V1 may be applied to selected bit lines BL. The first voltage V1 may be a reset voltage VRESET. The reset voltage VRESET may be a positive voltage. Unselected bit lines BL may be floated or supplied with a third voltage V3. The third voltage V3 may be a voltage having a level sufficient to prevent erasing of memory cells MC. Below, the inventive concept will be described under the condition that unselected bit lines 13L are floated. However, the inventive concept is not limited thereto.

A turn-on voltage VON may be provided to string selection lines. The turn-on voltage may be a power supply voltage VCC. A second voltage V2 may be supplied to word lines. The second voltage V2 may be a ground voltage VSS.

In an exemplary embodiment, FIG. 10A shows a voltage condition of bit lines, string selection lines, and word lines of a selected memory block to be erased. A voltage condition of an unselected memory block to be erase-inhibited may be identical to that illustrated in FIG. 6C.

FIG. 10B shows an example wherein voltages are applied to a selected memory block BLKa according to the voltage conditions in FIG. 10A. Referring to FIG. 10B, a first voltage V1 may be applied to a selected bit line BL 1, and an unselected bit line BL2 may be floated.

A turn-on voltage VON may be applied to string selection lines SSL1, SSL2, and a second voltage V2 may be applied to word lines WL1, WL2, WL3, WL4.

String selection transistors SST connected with the string selection lines SSL1, SSL2 may be turned on. The unselected bit line BL2 may be floated. That is, since no current can flow at memory cells MC of cell strings CS connected with the unselected bit line BL2, memory cells MC can not be erased. The first voltage V1 may be applied to the selected bit line BL1. A current may flow into word lines WL1, WL2, WL3, WL4 through the string selection transistors SST from the selected bit line BL1. That is, memory cells of cell strings CS connected with the selected bit line BL1 may be erased.

A second plane may be formed of memory cells MC corresponding to one bit line. When an erase operation is performed by a unit of at least second plane, string selection lines SSL1, SSL2 and word lines WL1, WL2, WL3, WL4 may be selected by a unit of at least one memory block BLKa, and bit lines BL1, BL2 may be selected by the bit line.

For example, when an erase operation is performed by a unit of a second plane, a bit line BL corresponding to the selected second plane may be selected, and word lines WL1, WL2, WL3, WL4 and string selection lines SSL1, SSL2 of the selected memory block BLKa all may be selected. If an erase operation is performed by a unit of two second planes, two bit line BL corresponding to the selected second planes may be selected, and word lines WL1, WL2, WL3, WL4 and string selection lines SSL1, SSL2 of the selected memory block BLKa all may be selected.

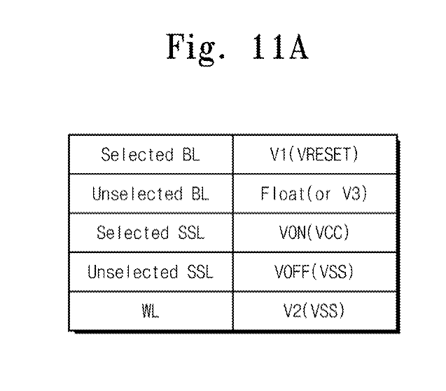

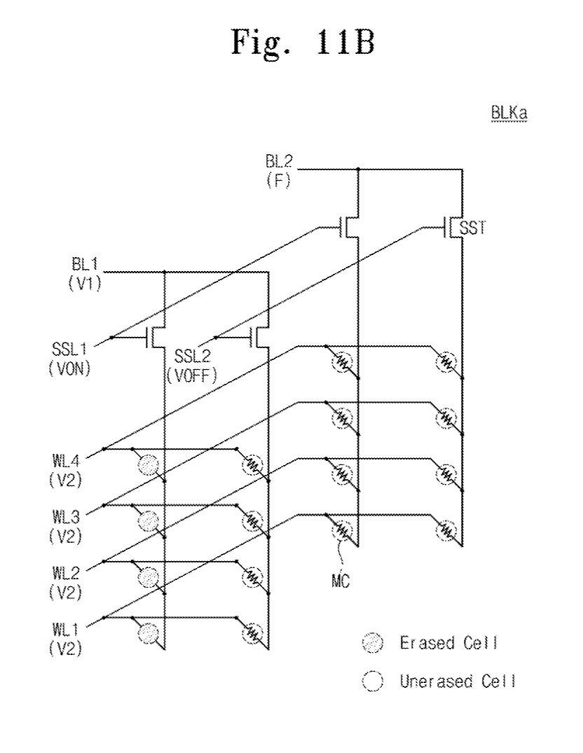

FIGS. 11A and 11B are diagrams illustrating an exemplary embodiment whereby an erase operation is performed by the cell string. Referring to FIG. 11A, there is illustrated a voltage condition of an erase operation executed by the cell string. A first voltage V1 may be applied to selected bit lines BL. The first voltage V1 may be a reset voltage VRESET. The reset voltage VRESET may be a positive voltage. Unselected bit lines BL may be floated or supplied with a third voltage V3. The third voltage V3 may be a voltage having a level sufficient to prevent erasing of memory cells MC. Below, the inventive concept will be described under the condition that unselected bit lines BL are floated. However, the inventive concept is not limited thereto.

A turn-on voltage VON may be provided to selected string selection lines SSL. The turn-on voltage VON may be a power supply voltage VCC. A turn-off voltage VOFF may be applied to unselected string selection lines SSL. The turn-off voltage VOFF may be a ground voltage VSS. A second voltage V2 may be supplied to word lines. The second voltage V2 may be a ground voltage VSS.

In an exemplary embodiment, FIG. 11A shows a voltage condition of bit lines, string selection lines, and word lines of a selected memory block to be erased. A voltage condition of an unselected memory block to be erase-inhibited may be identical to that illustrated in FIG. 6C.

FIG. 11B shows an example wherein voltages are applied to a selected memory block BLKb according to the voltage conditions in FIG. 11A. Referring to FIG. 11B, a first voltage may be applied to a selected bit line BL1, and unselected bit line BL2 may be floated.

The turn-on voltage VON may be applied to the selected string selection line SSL1, the turn-off voltage VOFF may be applied to the unselected string selection line SSL2, and the second voltage V2 may be applied to word lines WL1, WL2, WL3, WL4.

Since the unselected bit line BL2 is floated, memory cells MC of cell strings CS connected with the unselected bit line BL2 can not be erased. Since the turn-off voltage VOFF is applied to the unselected string selection line SSL2, memory cells MC of cell strings CS connected with the unselected string selection line SSL2 can not be erased. A current may flow through memory cells MC of cell strings CS connected with the selected BL1 and SSL.

When an erase operation is performed by a unit of at least one cell string, word lines WL1, WL4 may be selected by a unit of at least one memory block BLKa, bit lines BL1, BL2 may be selected by a unit of at least one bit line BL, and string selection lines SSL1, SSL2 may be selected by a unit of at least one string selection line SSL.

For example, when an erase operation is carried out by a unit of one cell string, one bit line BL corresponding to the selected cell string and one string selection line SSL may be selected, and all word lines WL1, WL2, WL3, WL4 of a selected memory block BLKa may be selected.

In the case where an erase operation is performed by a unit of two cell strings at different rows and the same column, two bit lines corresponding to two selected cell strings and one string selection line SSL may be selected, and all word lines WL1, WL2, WL3, WL4 of a selected memory block BLKa may be selected.

If an erase operation is performed by a unit of two cell strings at different columns and the same row, one bit line corresponding to two selected cell strings and two string selection lines SSL may be selected, and all word lines WL1, WL2, WL3, WL4 of a selected memory block BLKa may be selected.

When an erase operation is performed by a unit of two cell strings at different rows and different columns, two bit lines corresponding to two selected cell strings and two string selection lines SSL may be selected, and all word lines WL1, WL2, WL3, WL4 of a selected memory block BLKa may be selected.

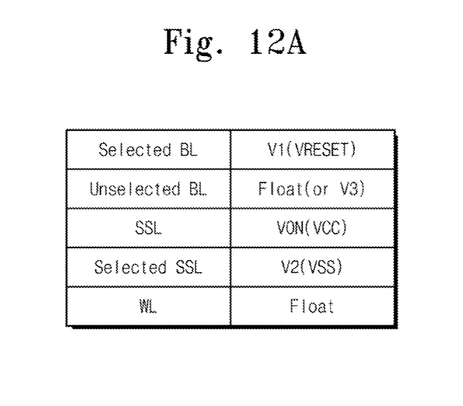

FIGS. 12A and 12B are diagrams illustrating an exemplary embodiment whereby an erase operation is performed by a unit of a row string. Referring to FIG. 12A, there is illustrated a voltage condition of an erase operation executed by a unit of a row string. A first voltage V1 may be applied to selected bit lines BL. The first voltage V1 may be a reset voltage VRESET. The reset voltage VRESET may be a positive voltage. Unselected bit lines BL may be floated or supplied with a third voltage V3. The third voltage V3 may be a voltage having a level sufficient to prevent erasing of memory cells MC. Below, the inventive concept will be described under the condition that unselected bit lines BL are floated. However, the inventive concept is not limited thereto.

A turn-on voltage VON may be provided to string selection lines SSL. The turn-on voltage VON may be a power supply voltage VCC. A second voltage V2 may be supplied to selected word lines. The second voltage V2 may be a ground voltage VSS. Unselected word lines may be floated.

In an exemplary embodiment, FIG. 12A shows a voltage condition of bit lines, string selection lines, and word lines of a selected memory block to be erased. A voltage condition of an unselected memory block to be erase-inhibited may be identical to that illustrated in FIG. 6C.

FIG. 12B shows an example wherein voltages are applied to a selected memory block BLKa according to the voltage conditions in FIG. 12A. Referring to FIG. 12B, a first voltage V1 may be applied to a selected bit line BL1, and an unselected bit line BL2 may be floated.

The turn-on voltage VON may be applied to the string selection lines SSL1, SSL2, and the second voltage V2 may be applied to a selected word line WL4. Unselected word lines WL1, WL2, WL3 may be floated.

Since the unselected bit line BL2 is floated, memory cells MC of cell strings CS connected with the unselected bit line BL2 can not be erased. Memory cells MC of cell strings CS connected with the unselected bit line BL2 can not be erased. A current may flow through memory cells MC of cell strings CS connected with the selected bit line BL1 and word line WL4. At this time, memory cells MC can be erased.

A row string may be formed of memory cells MC commonly corresponding to one bit line and one word line. When an erase operation is carried out by a unit of at least one row string, word lines WL1 and WL4 may be selected by a unit of at least one word line WL, bit lines BL1, BL2 may be selected by a unit of at least one bit line BL, and string selection lines SSL1, SSL2 may be selected by a unit of at least one memory block BLKa.

For example, when an erase operation is carried out by a unit of one row string, one bit line BL corresponding to the selected cell string and one word line WL may be selected, and all string selection lines SSL1, SSL2 of a selected memory block BLKa may be selected.

In the case where an erase operation is performed by a unit of two row strings at different rows and the same column, two bit lines corresponding to two selected cell strings and one word line WL may be selected, and all string selection lines SSL1, SSL2 of a selected memory block BLKa may be selected.

If an erase operation is performed by a unit of two cell strings at different heights and the same row, one bit line corresponding to two selected cell strings and two word lines WL may be selected, and all string selection lines SSL1, SSL2 of a selected memory block BLKa may be selected.

When an erase operation is performed by a unit of two cell strings at different rows and different heights, two bit lines corresponding to two selected cell strings and two word lines WL may be selected, and all string selection lines SSL1, SSL2 of a selected memory block BLKa may be selected.

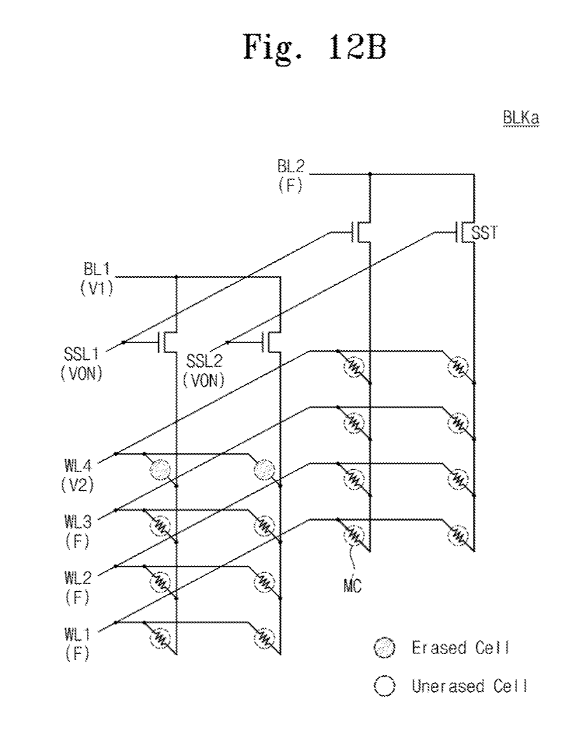

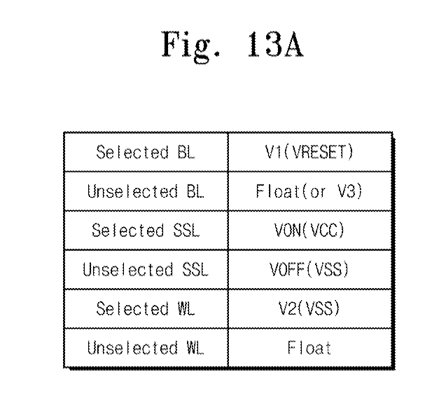

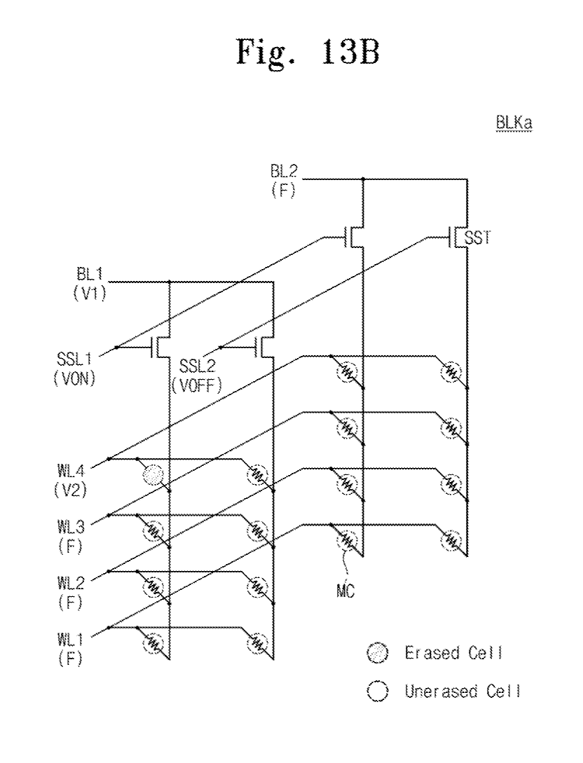

FIGS. 13A and 13B are diagrams illustrating an exemplary embodiment whereby an erase operation is performed by the memory cell. Referring to FIG. 13A, there is illustrated a voltage condition of an erase operation executed by the memory cell. A first voltage V1 may be applied to selected bit lines BL. The first voltage V1 may be a reset voltage VRESET. The reset voltage VRESET may be a positive voltage. Unselected bit lines BL may be floated or supplied with a third voltage V3. The third voltage V3 may be a voltage having a level sufficient to prevent erasing of memory cells MC. Below, the inventive concept will be described under the condition that unselected bit lines BL are floated. However, the inventive concept is not limited thereto.

A turn-on voltage VON may be provided to selected string selection lines SSL. The turn-on voltage VON may be a power supply voltage VCC. A turn-off voltage VOFF may be applied to unselected string selection lines SSL. The turn-off voltage VOFF may be a ground voltage VSS. A second voltage V2 may be supplied to selected word lines WL. The second voltage V2 may be a ground voltage VSS. Unselected word lines WL may be floated.

In an exemplary embodiment, FIG. 13A shows a voltage condition of bit lines, string selection lines, and word lines of a selected memory block to be erased. A voltage condition of an unselected memory block to be erase-inhibited may be identical to that illustrated in FIG. 6C.

FIG. 13B shows an example wherein voltages are applied to a selected memory block BLKa according to the voltage conditions in FIG. 13A. Referring to FIG. 13B, a first voltage V1 may be applied to a selected bit line BL1, and an unselected bit line BL2 may be floated.

The turn-on voltage VON may be applied to a selected string selection line SSL1, and the turn-off voltage VOFF may be applied to an unselected string selection line SSL2. The second voltage V2 may be applied to a selected word line WL4. Unselected word lines WL1 to WL3 may be floated.

Since the unselected bit line BL2 is floated, memory cells MC of cell strings CS connected with the unselected bit line BL2 can not be erased. Memory cells MC of cell strings CS connected with the unselected word lines WL1, WL2, WL3 can not be erased. Memory cells MC of cell strings CS connected with the unselected string selection line SSL2 can not be erased. A current may flow through memory cells MC corresponding to the selected BL1, SSL, and WL4. At this time, memory cells MC may be erased.

When an erase operation is carried out by a unit of at least one memory cell, word lines WL1, WL4 may be selected by a unit of at least one word line WL, bit lines BL1, BL2 may be selected by a unit of at least one bit line BL, and string selection lines SSL1, SSL2 may be selected by a unit of at least one sting selection line SSL.

For example, when an erase operation is carried out by a unit of one memory cell, one bit line BL corresponding to the selected memory cell, one string selection line SSL, and one word line WL may be selected.

When an erase operation is performed by a unit of two memory cells MC at the same row, the same column, and different heights, one bit line BL corresponding to the two selected memory cells, one string selection line SSL, and two word lines WL may be selected.

When an erase operation is performed by a unit of two memory cells MC at the same row, different columns, and the same height, one bit line BL corresponding to the two selected memory cells, two string selection lines SSL, and one word line WL may be selected.

When an erase operation is performed by a unit of two memory cells MC at different rows, the same column, and the same height, two bit lines BL corresponding to the two selected memory cells, one string selection line SSL, and one word line WL may be selected.

When an erase operation is performed by a unit of two memory cells MC at the same row, different columns, and different heights, one bit line BL corresponding to the two selected memory cells, two string selection lines SSL, and two word lines WL may be selected.

When an erase operation is performed by a unit of two memory cells MC at different rows, the same column, and different heights, two bit lines BL corresponding to the two selected memory cells, one string selection line SSL, and two word lines WL may be selected.

When an erase operation is performed by a unit of two memory cells MC at different rows, different columns, and the same height, two bit lines BL corresponding to the two selected memory cells, two string selection lines SSL, and one word line WL may be selected.

When an erase operation is performed by a unit of two memory cells MC at different rows, different columns, and different heights, two bit lines BL corresponding to the two selected memory cells, two string selection lines SSL, and two word lines WL may be selected.

FIG. 14 is a flowchart illustrating an erase method according to an exemplary embodiment of the inventive concept. Referring to FIGS. 1 and 14, in operation S210, an erase unit may be selected. In operation S220, an erase operation may be performed according to the selected erase unit. In an exemplary embodiment, the erase unit may vary according to the characteristics of RRAM 100. For example, the erase unit may be selected in view of parameters such as a capacity of a charge pump of the RRAM 100, the used amount of the charge pump, an erase speed, a response time, and the like. The erase unit can be selected when the RRAM 100 is fabricated. The erase unit can be changed or selected according to parameters of the RRAM 100 or data when the RRAM 100 is in use.

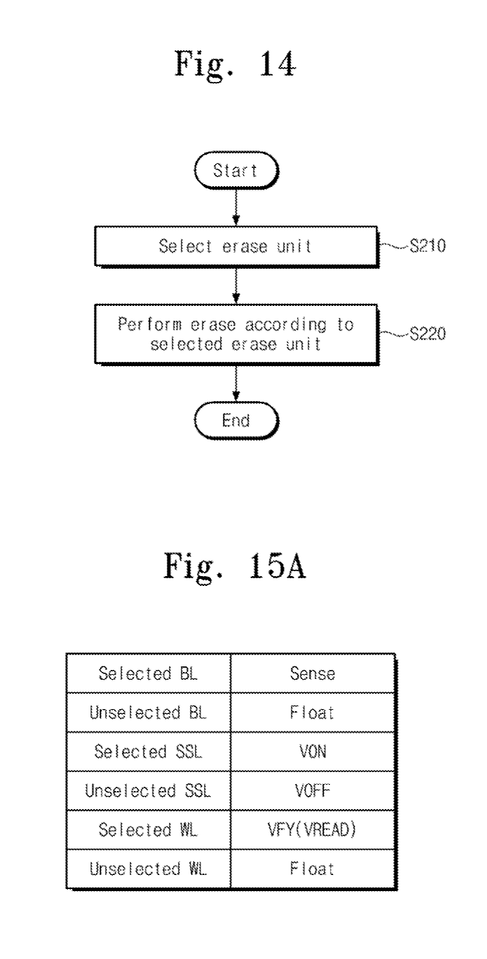

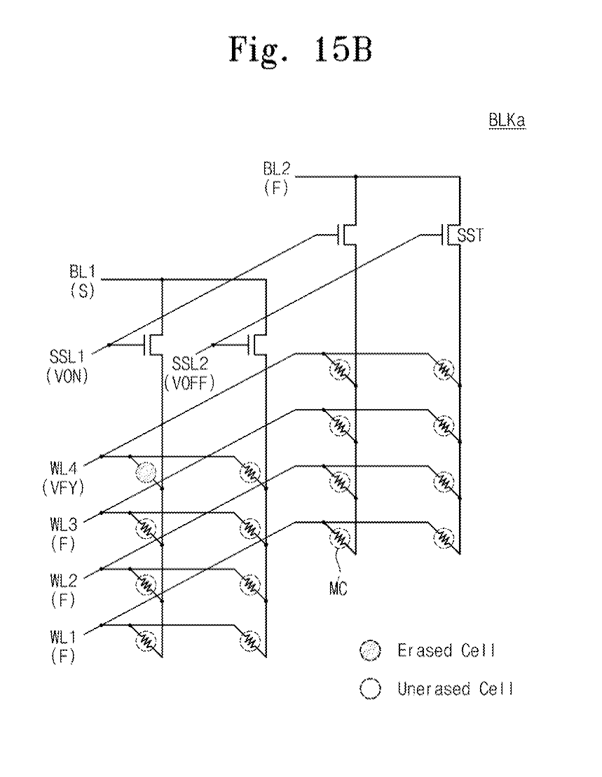

FIGS. 15A and 15B are diagrams illustrating an example of an erase verification operation, that is, verifying whether an erase operation has passed or failed. In an exemplary embodiment, an erase verification operation may be performed after an erase operation is carried out. An erase verification unit may be less than an erase unit. When the erase verification unit is less than the erase unit, the erase verification operation may be iterated until all erased memory cells are erase-verified.

An example wherein an erase verification operation is performed by a unit of a memory cell is illustrated in FIGS. 15A and 15B. As described in relation to FIGS. 6A to 13B, the erase verification unit may be varied.

Referring to FIG. 15A, selected bit lines BL may be sensed. Unselected bit lines BL may be floated. A turn-on voltage VON may be applied to selected string selection lines SSL. The turn-on voltage VON may be a power supply voltage VCC. A turn-off voltage VOFF may be provided to unselected string selection lines SSL. The turn-off voltage VOFF may be a ground voltage VSS. A verification voltage VFY may be supplied to selected word lines WL. The verification voltage VFY may be a read voltage VREAD having a level corresponding to a read period depicted in FIG. 4. Unselected word lines WL may be floated.

FIG. 15B shows an example wherein voltages are applied to a selected memory block BLKa according to a voltage condition in FIG. 15A. Referring to FIG. 15B, a selected bit line BL1 may be sensed, and an unselected bit line BL2 may be floated.

A turn-on voltage VON may be provided to a selected string selection line SSL1, and a turn-off voltage VOFF may be applied to an unselected string selection line SSL2. A verification voltage VFY may be supplied to a selected word line WL4. Unselected word lines WL1, WL2, WL3 may be floated.

No current can flow at memory cells corresponding to the unselected bit line BL2, the unselected string selection line SSL2, and the unselected word lines WL1 to WL3. A current may flow into the selected bit line BL1 from the selected word line WL1 through memory cells connected with the selected word line WL4 and corresponding to the selected string selection line SSL1. That is, memory cells MC may be verified.

For example, the amount of current flowing through selected bit lines BL may be detected, and the detected current amount may be compared with a reference current amount. When a difference between the detected current amount and the reference current amount is below a reference, an erase operation may be determined to have passed. When a difference between the detected current amount and the reference current amount is over the reference, an erase operation may be determined to have failed.

When an erase verification operation is performed by a unit of at least one memory cell, at least one reference memory cell may be provided. Erase pass or fail may be determined by comparing a current flowing through at least one memory cell with a reference current flowing through at least one reference memory cell.

Likewise, when the erase verification operation is performed by a unit of at least one memory block, at least one first plane, at least one word line, at least one cell string at least one second plane, or at least one row string, at least one reference memory block, at least one reference first plane, at least one reference word line, at least one reference cell string at least one reference second plane, or at least one reference row string may be provided.

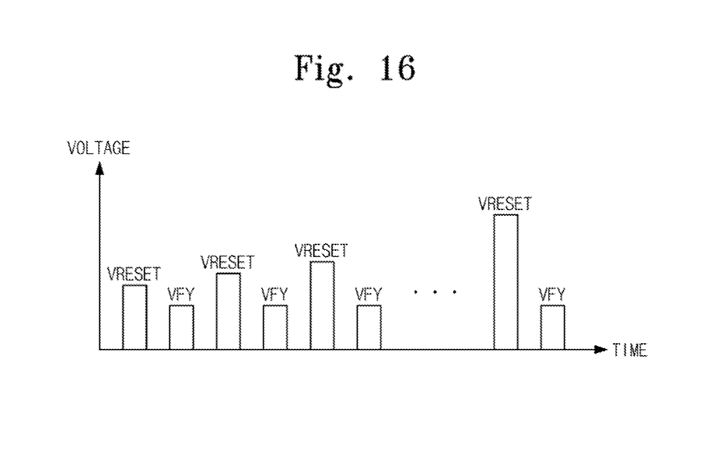

FIG. 16 is a diagram illustrating an example wherein an erase operation and an erase verification operation are iterated. In FIG. 16, the horizontal axis indicates time and the vertical axis indicates a voltage. Referring to FIG. 16, an erase operation may be performed by applying a reset voltage VRESET. Then, an erase verification operation may be carried out by applying a verification voltage VFY. If selected memory cells are determined to be erase-failed, the reset voltage VRESET may again be applied. At this time, a level of the reset voltage VRESET may increase. An erase operation and an erase verification operation may be iterated until selected memory cells are erase-passed. At this time, a level of the reset voltage VRESET may increase. That is, an incremental step pulse erase scheme may be used.

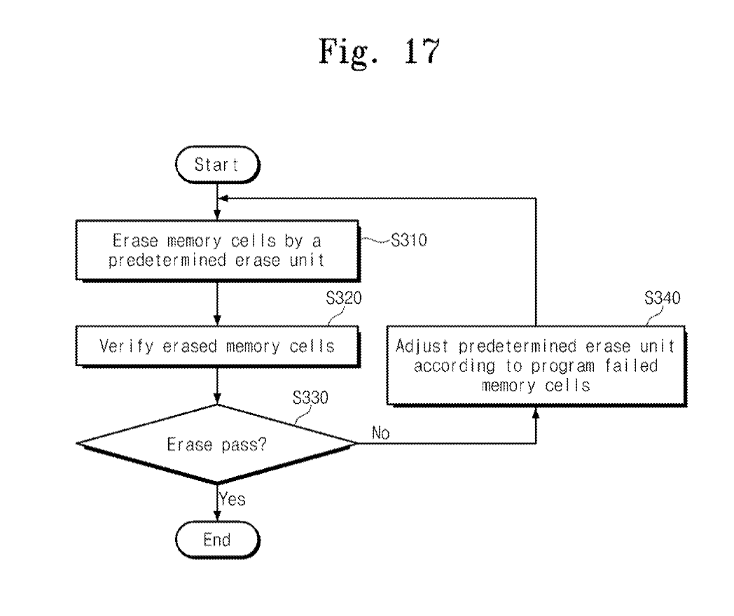

FIG. 17 is a flowchart illustrating an erase method according to an exemplary embodiment of the inventive concept. Referring to FIG. 17, in operation S310, memory cells may be erased by a predetermined erase unit. For example, memory cells may be erased by a memory block unit as described with reference to FIGS. 6A to 6C. Memory cells may be erased by a unit of a first plane as described with reference to FIGS. 7A and 7B. As described with reference to FIGS. 8A and 8B, memory cells may be erased by a word line unit. Memory cells may be erased by a page unit as described with reference to FIGS. 9A and 9B. As described with reference to FIGS. 10A and 10B, memory cells may be erased by a unit of a second plane. Memory cells may be erased by a cell string unit as described with reference to FIGS. 11A and 11B. As described with reference to FIGS. 12A and 12B, memory cells may be erased by a row string unit. Memory cells may be erased by a memory cell unit as described with reference to FIGS. 13A and 13B.

In operation S320, erased memory cells may be verified. An erase verification operation may be performed the same as described with reference to FIGS. 15A and 15B. The erase verification operation may be performed by the same unit as the erase operation (S310).

In operation S330, whether memory cells are erase-passed may be determined. If so, the method may be ended. If not, the predetermined erase unit may be adjusted according to erase-failed memory cells.

For example, when erase-failed memory cells form a memory block, the predetermined erase unit may be adjusted to a memory block unit. If erase-failed memory cells form a first plane, the predetermined erase unit may be adjusted to a first plane unit. When erase-failed memory cells form a word line unit, the predetermined erase unit may be adjusted to a word line unit. When erase-failed memory cells form a page, the predetermined erase unit may be adjusted to a page unit. In case that erase-failed memory cells form a second plane, the predetermined erase unit may be adjusted to a second plane unit. When erase-failed memory cells form a cell string, the predetermined erase unit may be adjusted to a cell string unit. If erase-failed memory cells form a row string, the predetermined erase unit may be adjusted to a row string unit. When erase-failed memory cells form a memory cell unit, the predetermined erase unit may be adjusted to a memory cell unit.

Operations S310, S320, and 330 may then be re-performed. When the operation S310 is re-performed, a level of the reset voltage VRESET may increase as described with reference to FIG. 16.

As described above, if erase-failed memory cells exist after memory cells are erased, an erase operation and an erase verification operation may be iterated only with respect to the erase-failed memory cells. When erase-failed memory cells correspond to at least two erase units of erase units described with reference to FIGS. 6A to 13B, an erase operation and an erase verification operation may be performed according to two or more erase units.

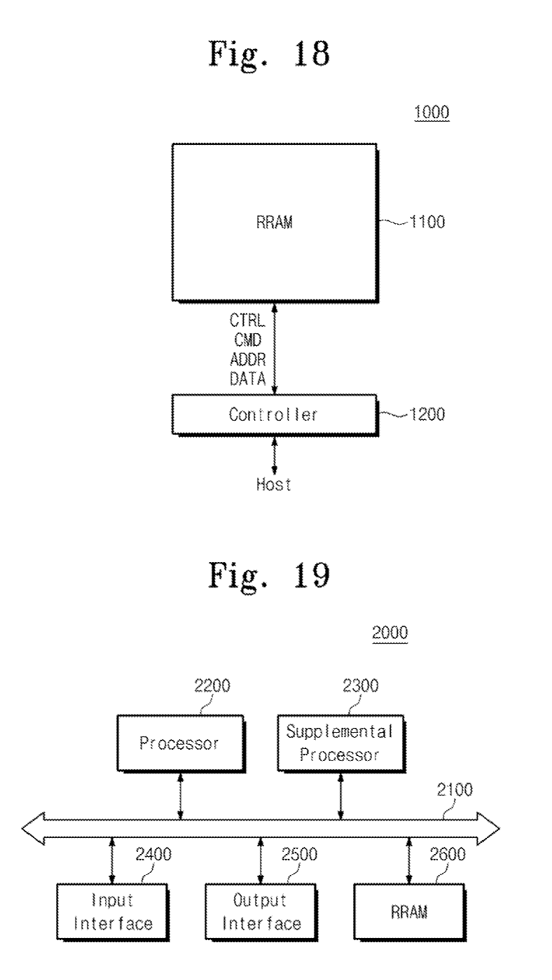

FIG. 18 is a block diagram illustrating a memory system according to an exemplary embodiment of the inventive concept. Referring to FIG. 18, a memory system 1000 may include an RRAM 1100 and a controller 1200.

The RRAM 1100 may include an RRAM as described with reference to FIGS. 1 to 17.

The controller 1200 may be configured to control the RRAM 1100. The controller 1200 may control programming, reading, and erasing of the RRAM 1100. The controller 1200 may provide a control signal CTRL, a command CMD, and an address ADDR to the RRAM 1100, and may exchange data with the RRAM 1100.

In an exemplary embodiment, the controller 1200 may include components such as a RAM, a processing unit, a host interface, and a memory interface. The RAM may be used as at least one of a cache memory between the RRAM 1100 and a host and a buffer memory between the RRAM 1100 and the host. The processing unit may control the overall operation of the controller 1200.

The host interface may communicate with the RRAM 1100 according to the specific communications standard. In an exemplary embodiment, the controller 1200 may communicate with an external device (e.g., the host) via at least one of various communications standards such as Universal Serial Bus (USB), multimedia card (MMC), peripheral component interconnection (PCI), PCI-express (PCI-E), Advanced Technology Attachment (ATA), Serial-ATA, Parallel-ATA, small computer small interface (SCSI), enhanced small disk interface (ESDI), Integrated Drive Electronics (IDE), and Firewire. The memory interface may interface with the RRAM 1100. The memory interface may include a NAND interface or a NOR interface.

The memory system 1000 may be configured to further include an error detecting and correcting block. The error detecting and correcting block may be configured to detect and correct an error of data read from the RRAM 1100 using ECC data (or, parity data). In an exemplary embodiment, the error detecting and correcting block may be provided as a constituent element of the controller 1200. In other exemplary embodiments, the error detecting and correcting block may be provided as a constituent element of the RRAM 1100.

The controller 1200 and the RRAM 1100 may be integrated to one semiconductor device. The controller 1200 and the RRAM 1100 may be integrated to one semiconductor device to form a memory card. For example, the controller 1200 and the RRAM 1100 may be integrated to one semiconductor device to form a memory card such as a personal computer (PC) or, Personal Computer Memory Card International Association (PCMCIA) card, a Compact Flash (CF) card, a SmartMedia (SM) card, a memory stick, a multimedia card (MMC, RS-MMC, MMCmicro), a secure digital card (SD, miniSD, SDHC), a Universal Flash Storage (UFS) device, or the like.

The controller 1200 and the RRAM 1100 may be integrated into one semiconductor device to form a Solid State Drive (SSD). The SSD may include a storage device which is configured to store data using semiconductor memories. When the memory system 1000 is used as the SSD, an operating speed of a host connected with the memory system 1000 may be remarkably improved.

In an exemplary embodiment, the memory system 1000 may be used as computer, portable computer, Ultra Mobile PC (UMPC), workstation, net-book, PDA, web tablet, wireless phone, mobile phone, smart phone, e-book, PMP (portable multimedia player), digital camera, digital audio recorder/player, digital picture/video recorder/player, portable game machine, navigation system, black box, 3-dimensional television, a device capable of transmitting and receiving information at a wireless circumstance, one of various electronic devices constituting home network, one of various electronic devices constituting computer network, one of various electronic devices constituting telematics network, RFID, or one of various electronic devices constituting a computing system.

In an exemplary embodiment, an RRAM 1100 or a memory system 1000 may be packed by various types of packages such as Package on Package (PoP), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

FIG. 19 is a block diagram schematically illustrating a computing system according to an exemplary embodiment of the inventive concept. Referring to FIG. 19, a computing system 2000 may include a system bus 2100, a processor 2200, a supplemental processor 2300, an input interface 2400, an output interface 2500, and a RAM 2600.

The system bus 2100 may provide channels among elements of the computing system 2000.

The processor 2200 may be configured to control the overall operation of the computing system 2000. The processor 2200 may include a general-purpose processor or an application processor (AP).

The supplemental processor 2300 may be configured to supplement an operation of the processor 2200. The supplemental processor 2300 may include an image processor (or, codec), a sound processor (or, codec), a compression or de-compression processor (or, codec), an encoding or decoding processor (or, codec).

The input interface 2400 may include devices receiving signals from an external device. The input interface 2400 may include at least one input device such as a button, a keyboard, a mouse, a microphone, a camera, a touch panel, a touch screen, or a wire/wireless receiver.

The output interface 2500 may include devices outputting signals to the external. The output interface 2500 may include at least one output device such as a monitor, a ramp, a speaker, a printer, a motor, or a wire/wireless transmitter.

The RAM 2600 may be used as a working memory of the computing system 2000. The RAM 2600 may include an RRAM 100 according to an exemplary embodiment of the inventive concept as described in relation to FIG. 1 or 17.

As described above, the RRAM 100 of the inventive concept may control bit line BL, string selection lines SSL, and word lines WL to erase memory cells MC. Since a leakage current is prevented and selectivity of memory cells is improved, it is possible to provide an erase method of an RRAM with the improved reliability.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. An erase method of a resistive random access memory which includes a plurality of cell strings each having a plurality of memory cells and a string selection transistor, the erase method comprising:
applying a first voltage to bit lines connected with string selection transistors of the plurality of cell strings;
applying a turn-on voltage to at least one string selection line selected from string selection lines connected with the string selection transistors;
applying a turn-off voltage to unselected string selection lines of the string selection lines;
applying a second voltage to at least one word line selected from word lines connected with memory cells of the plurality of cell strings; and
floating unselected word lines of the word lines.

2. The erase method of claim 1, wherein the first voltage and the second voltage are established to reset a selected memory cell.

3. The erase method of claim 1, wherein the second voltage is a ground voltage.

4. The erase method of claim 1, wherein the string selection lines and the word lines are selected by a unit of at least one memory block.

5. The erase method of claim 1, wherein the word lines are selected by a unit of at least one memory block and the string selection lines are selected by a unit of at least one string selection line.

6. The erase method of claim 1, wherein the word lines are selected by a unit of at least one word line and the string selection lines are selected by a unit of at least one memory block.

7. The erase method of claim 1, wherein the word lines are selected by a unit of at least one word line and the string selection lines are selected by a unit of at least one string selection line.

8. The erase method of claim 1, further comprising:
selecting one of a plurality of erase units;
wherein a number of the selected at least one word line and a number of the selected at least one string selection line vary according to the selected erase unit.

9. The erase method of claim 1, further comprising performing an erase verification operation; and
wherein the erase verification operation comprises:
applying a turn-on voltage to the selected at least one string selection line;
applying a turn-off voltage to the unselected string selection lines;
applying a verification voltage to the selected at least one word line;
floating the unselected word lines; and
sensing a current flowing through the bit lines.

10. The erase method of claim 1,
further comprising erasing again the plurality of memory cells when the erase verification operation is determined to have failed,
wherein erasing again comprises:
applying a third voltage higher than the first voltage to the bit lines connected with the string selection transistors of the plurality of cell strings;
applying the turn-on voltage to the at least one string selection line selected from the string selection lines connected with the string selection transistors;
applying the turn-off voltage to the unselected string selection lines of the string selection lines;
applying the second voltage to the at least one word line selected from the word lines connected with the memory cells of the plurality of cell strings; and
floating the unselected word lines of the word lines.

11. An erase method of a resistive random access memory which includes a plurality of cell strings each having a plurality of memory cells and a string selection transistor, the erase method comprising:
applying a first voltage to at least one bit line selected from bit lines connected with string selection transistors of the plurality of cell strings;
floating unselected bit lines of the bit lines;
applying a turn-on voltage to at least one string selection line selected from string selection lines connected with the string selection transistors;
applying a turn-off voltage to unselected string selection lines of the string selection lines;
applying a second voltage to at least one word line selected from word lines connected with memory cells of the plurality of cell strings; and
floating unselected word lines of the word lines.

12. The erase method of claim 11, wherein the bit lines are selected by a unit of at least one bit line, the string selection lines are selected by a unit of at least one memory block, and the word lines are selected by a unit of at least one memory block.

13. The erase method of claim 11, wherein the bit lines are selected by a unit of at least one bit line, the string selection lines are selected by a unit of at least string selection line, and the word lines are selected by a unit of at least one memory block.

14. The erase method of claim 11, wherein the bit lines are selected by a unit of at least one bit line, the string selection lines are selected by a unit of at least one memory block, and the word lines are selected by a unit of at least one word line.

15. The erase method of claim 11, wherein the bit lines are selected by a unit of at least one bit line, the string selection lines are selected by a unit of at least string selection line, and the word lines are selected by a unit of at least one word line.

16. The erase method of claim 11, further comprising:
selecting one of a plurality of erase units; and
wherein the number of the selected at least one bit line, the number of the selected at least word line, and the number of the selected at least one string selection line vary according to the selected erase unit.

17. A method of controlling erasure and non-erasure of resistive random access memory cell strings of a memory array, the method comprising:
coupling the resistive random access memory cell strings to a bit line, a current flowing through the memory cell strings being controlled by a voltage applied to a respective string selection transistor of each resistive random access memory cell string, each cell of the memory string being coupled to a respective word line;
erasing the resistive random access memory cell strings by:
applying a first voltage to the bit line;
applying a turn-on voltage to each respective string selection transistor, and
applying a second voltage to each word line; and
non-erasing the resistive random access memory cell strings by:
applying the first voltage to the bit line;
applying a turn-off voltage to each respective string selection transistor; and
floating each word line.

18. The method of claim 17, wherein the first voltage is a positive reset voltage.

19. The method of claim 17, wherein the turn-on voltage is a power supply voltage.

20. The method of claim 17, wherein the turn-off voltage and the second voltage are ground voltages.
